(19) United States
(12) Patent Application Publication
(10) Pub. No.: US 2011/0192960 A1
(43) Pub. Date: Aug. 11, 2011

(54) OPTICAL SENSING DEVICE WITH ANTI-STATIC MEMBER

(75) Inventors: CHUNG-PING FENG, HSINCHU COUNTY (TW); PENG-YU CHEN, TAIPEI CITY (TW)

(73) Assignee: EDISON OPTO CORPORATION, TAIPEI HSIEN (TW)

(21) Appl. No.: 12/757,402

(22) Filed: Apr. 9, 2010

(30) Foreign Application Priority Data
Feb. 8, 2010 (TW) 099103774

(51) Int. Cl. H01L 31/167; H01L 31/02; H01L 31/0232

(52) U.S. Cl. 250/214 R; 250/232; 250/221

(57) ABSTRACT

An optical sensing device, which includes a shell, at least one light emitting member, a shading member, at least one anti-static member and at least one optical sensing member, is disclosed. The shell is formed with a black-body condition space therein, and the black-body condition space has a light emitting chamber, a shading chamber and at least one optical sensing chamber. The light emitting member projects a light beam into the light emitting chamber. The shading member is movably restrained within the shading chamber, and generates a static electricity when moving therein. The anti-static member is arranged in the shading chamber to ground the static electricity. The optical sensing member is arranged in the optical sensing chamber, and senses the light beam to accordingly send out a sensing signal.

This application claims the benefit of Taiwan Patent Application Serial No. 099103774, filed Feb. 8, 2010, the subject matter of which is incorporated herein by reference.

### FIELD OF THE INVENTION

The present invention relates to an optical sensing device, and more particularly to an optical sensing device with at least one anti-static member.

### BACKGROUND OF THE INVENTION

In daily life, it is usually necessary to use some sensor to obtaining the inclined angle or the movement data of an object. These sensors usually can provide the functions of sensing horizontal movement, vertical movement or inclined angle. Practically, many sensing technologies, such as optical sensing technologies, sound wave sensing technologies, or electrical sensing technologies, may be applied to these sensors. Among these sensing technologies, the optical sensing technologies have the advantage of rapid sensing, so that the optical sensing technologies are widely applied to manufacture some optical sensing devices with high sensing sensitivity.

Among the present optical sensing devices, most of them are provided with a shell having a black-body condition space therein. In the black-body condition space, a light emitting member, a shading member and at least one optical sensing member are arranged, so as to make sure that the optical sensing can exactly execute the function of optical sensing without being interfered by the light pollution generated from the outer environment.

In the optical sensing device, the light emitting member projects a light beam. The shading member is movably arranged within the black-body condition space, so as to move by the action of gravity or inertial force when the optical sensing device is moved or tilted, and further to accordingly change the relative position of the shading member with respect to the light emitting member and the optical sensing member.

When the relative positions of the shading member with respect to the light emitting member and the optical sensing member are changed, the reflection angle and the path of the light beam are also be changed to make the intensity of the light beam that the optical sensing member senses is changed together with above changes, so as to accordingly judge or calculate the parameters of horizontal movement, vertical movement, and the inclination angle, etc.

However, in above conventional optical sensing technology, it is unavoidable that exists a problem that a static electricity is generated when the shading member moves. Under the influence of the static electricity, it also brings more negative influence to the exactness of the optical sensing device. Based on above background, the inventor is of the opinion that it is necessary to develop a new optical sensing technology to reduce or prevent the negative influence to the exactness of the optical sensing device caused by static electricity.

### SUMMARY OF THE INVENTION

Due to that there is a serious problem that the static electricity brings negative influence to the exactness of the optical sensing device in the prior arts, the primary objective of the present invention is to provide an optical sensing device, in which at least one anti-static member is arranged in the position where the static electricity is easily generated, so as to instantly grounding the static electricity out of the black-body condition space.

Means of the present invention for solving the problems as mentioned above provides an optical sensing device, which comprises a shell, at least one light emitting member, a shading member, at least one anti-static member and at least one optical sensing member. The shell is formed with a black-body condition space therein, and the black-body condition space has a light emitting chamber, a shading chamber and at least one optical sensing chamber. The light emitting member projects a light beam into the light emitting chamber. The shading member is movably restrained within the shading chamber, and generates a static electricity when moving therein. The anti-static member is arranged in the shading chamber to ground the static electricity. The optical sensing member is arranged in the optical sensing chamber, and senses the light beam to accordingly send out a sensing signal.

In the preferred embodiments of the present invention, the optical sensing device further comprises a circuit board, and the shell is assembled with the circuit board to form the black-body condition space. The anti-static member can be an anti-static circuit or an anti-static layer deposited on the circuit board, or can be an anti-static coating coated in the shading chamber. Preferably, the anti-static coating can be formed by a vapor deposition process, a sputtering process, or a spray coating process. The light emitting member can be a light emitting diode (LED), and the optical sensing member can be a photo transistor or a photo diode.

Comparing with the optical sensing device as disclosed in prior arts, in the present invention, an anti-static member is arranged in the action region of the shading chamber; therefore, no matter the shading member moves to any position of the action region, it always can ground the static electricity, which is generated during the movement, via the anti-static member, so as to effectively reduce or prevent the negative influences to the exactness of the optical sensing device caused by the static electricity, and further to improve the exactness for sensing the variation of the movement or inclination angle.

The devices, characteristics, and the preferred embodiment of this invention are described with relative figures as follows.

### BRIEF DESCRIPTION OF THE DRAWINGS

The structure and the technical means adopted by the present invention to achieve the above and other objectives can be best understood by referring to the following detailed description of the preferred embodiments and the accompanying drawings, wherein

FIG. 1 is a three dimensional view of an optical sensing device in accordance with a first embodiment of the present invention;

FIG. 2 is a perspective view of the optical sensing device after the shell is apart from the circuit board in accordance with the first embodiment of the present invention;

FIG. 3 illustrates the structure of the shell in accordance with the first embodiment of the present invention;

FIG. 4 illustrates the working principle in accordance with the first embodiment of the present invention;

FIG. 5 is a three dimensional view of an optical sensing device in accordance with a second embodiment of the present invention;

FIG. 6 is a perspective view of the optical sensing device after the shell is apart from the circuit board in accordance with the second embodiment of the present invention;

FIG. 7 illustrates the structure of the shell in accordance with the second embodiment of the present invention;

FIG. 8 illustrates the projection direction of the light beam in accordance with the second embodiment of the present invention; and

FIG. 9 illustrates the working principle of that the optical sensing device is capable of sensing external relative position of an object.

### DETAILED DESCRIPTION OF THE PREFERRED EMBODIMENTS

The optical sensing device as provided in accordance with the present invention can be widely applied to sense the movement or the inclined angle of many kinds of objects, and the combined applications of the present invention are too numerous to be enumerated and described, so that only two preferred embodiments are disclosed as follows for representation.

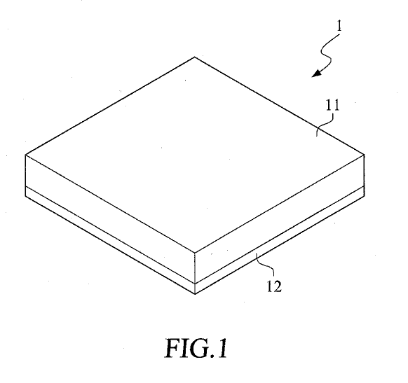

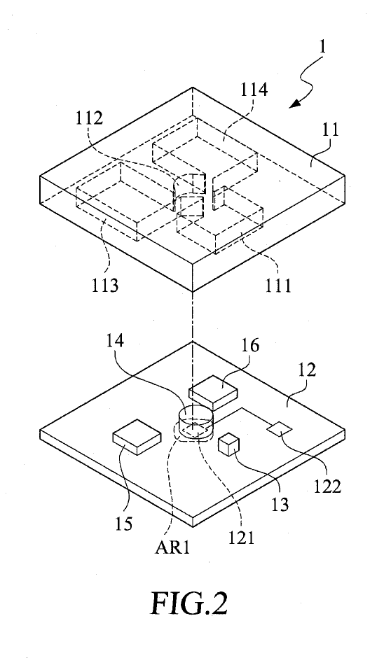

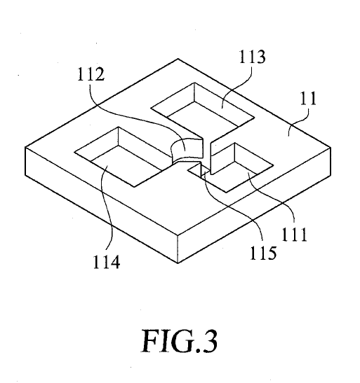

Please refer to FIG. 1 to FIG. 4. In a first embodiment of the present invention, an optical sensing device 1 comprises a shell 11, a circuit board 12, a light emitting member 13, a shading member 14 and two optical sensing members 15 and 16. The shell 11 and the circuit 12 are assembled together to form a black-body condition space therein. As shown in FIG. 3, the black-body condition space has a light emitting chamber 111, and a shading chamber 112, and two optical sensing chambers 113 and 114. The shading chamber 112 is spatially communicated with the light emitting chamber 111, and the optical sensing chambers 113 and 114. An anti-static member 115 is arranged in the shading chamber 112. Furthermore, the anti-static member 115 can be an anti-static coating partially or fully coated on the inner wall of the shading chamber 112.

The circuit board 12 is arranged with another anti-static member 121 and a grounding circuit 122, and the anti-static members 115 and 121 are electrically connected with the grounding circuit 122, so as to keep the anti-static members 115 and 121 in a grounding situation. Meanwhile, the anti-static member 121 is arranged on the circuit board 12 with respect to the shading chamber 112, and can be an anti-static circuit or an anti-static layer. When the anti-static member 115 is an anti-static coating, it can be extended out from the shading chamber 112 to contact with the grounding circuit 122 of the circuit board 12.

The light emitting member 13 is arranged in the light emitting chamber 111, and can be a light emitting diode (LED). The shading member 14 is movably restrained in an action region AR1 within the shading chamber 112. In other words, the shading member 14 is restrained in the condition that it only can move within the action region AR1. It is more important that the shading member 14 always keeps in contacting with at least one of the anti-static members 115 and 121 when it moves within the action region AR1. The optical sensing members 15 and 16 are respectively arranged in the optical sensing chambers 113 and 114, and can be a photo transistor or a photo diode.

Preferably, the anti-static coating can be formed by a vapor deposition process, a sputtering process or a spray coating process. The anti-static circuit and the anti-static layer are made of conductive material selected from one of metal, metal alloy, metal oxide, nonmetal, or the combination thereof. In the first embodiment of the present invention, the optical sensing device 1 has two anti-static members 115 and 121 arranged in the shading chamber 112; however, it is also able to execute the technology as disclosed in the present invention by just arranging either one of the anti-static members 115 and 121. Moreover, though that in the first embodiment, it is necessary to electrically connected both the anti-static members 115 and 121 to the grounding circuit 122; in practical applications, it is also unnecessary to provide the anti-static function by electrically connected to the grounding circuit 122 if the anti-static members 115 and 121 themselves have sufficient ability of absorbing or reducing the static electricity.

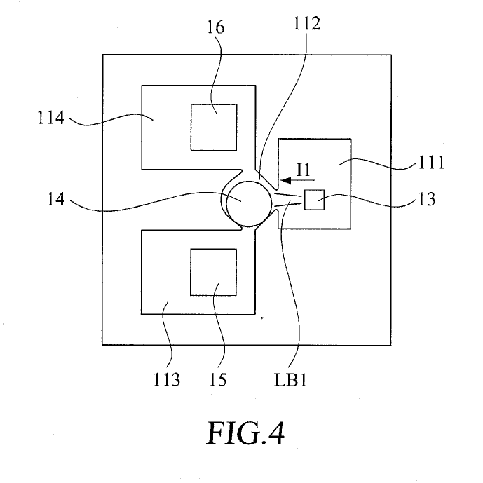

As shown in FIG. 4, an object (not shown), which needs to be sensed, can be an electronic device, such as a digital camera, a personal digital assistant (PDA), or a mobile phone. When the optical sensing device 1 is operated to sense the inclination angle or the movement of the object, it is able to embed the optical sensing device 1 into the object or connect the optical sensing device 1 to the object, and make the light emitting member 13 project a light beam LB1 into the light emitting chamber 111 along a projection direction I1. At this moment, the light beam LB1 projects to the shading member 14 restrained in the shading chamber 112 along the projection direction I1, illuminates the black-body condition space after being reflected from the shading member 14 or the inner wall of the shell 11 for at least one time, and is further sensed by the optical sensing members 15 and 16.

When the object is moved or lifted along a first direction, the shading member 14 surfers an inertia force or a gravity force. When the component of the inertia force or the gravity force along the surface, that the shading member 14 substantially contacts with the circuit board 12, is greater than the friction force between the shading member 14 and the circuit board 12, the shading member 14 moves along a second direction opposite to the first direction, and then a static electricity is generated. At this moment, the static electricity is instantly transmitted to the grounding circuit 122 via at least one of the anti-static members 115 and 121, and then the static electricity is grounded out.

At the same time, the shading member 14 changes its position within the action region AR1 according to the movement or the inclination of the object, so as to make the reflection angle and the path of the light beam LB1 also be changed in accordance with the position of the shading member 14 within the action region AR1. Then, the intensities of the light beam LB1 sensed by the optical sensing members 15 and 16 are also changed in accordance with the change of the reflection angle and the path of the light beam LB1, so as to accordingly judge and calculate the parameter(s) of horizontal movement, vertical movement and/or inclination angle, and further to accordingly send out a sensing signal according to the parameter(s).

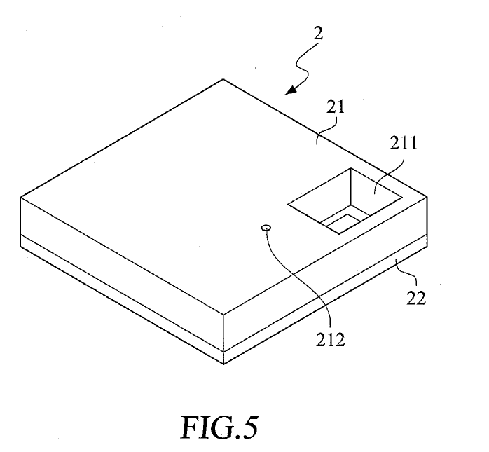

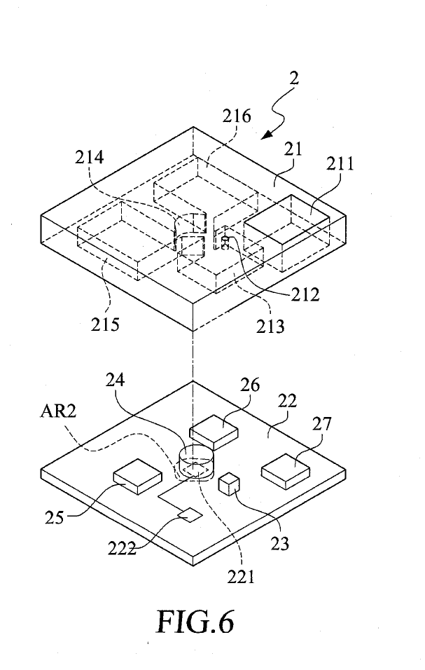

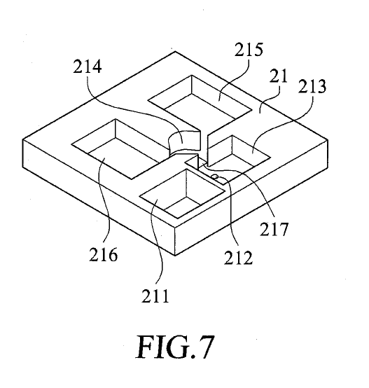

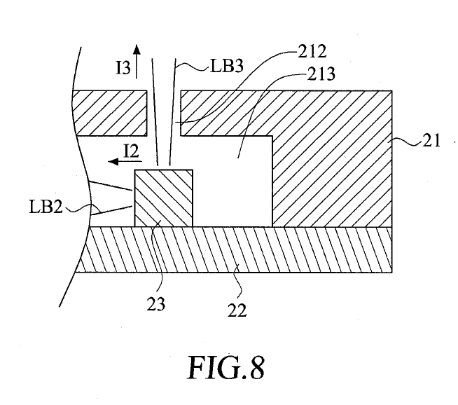

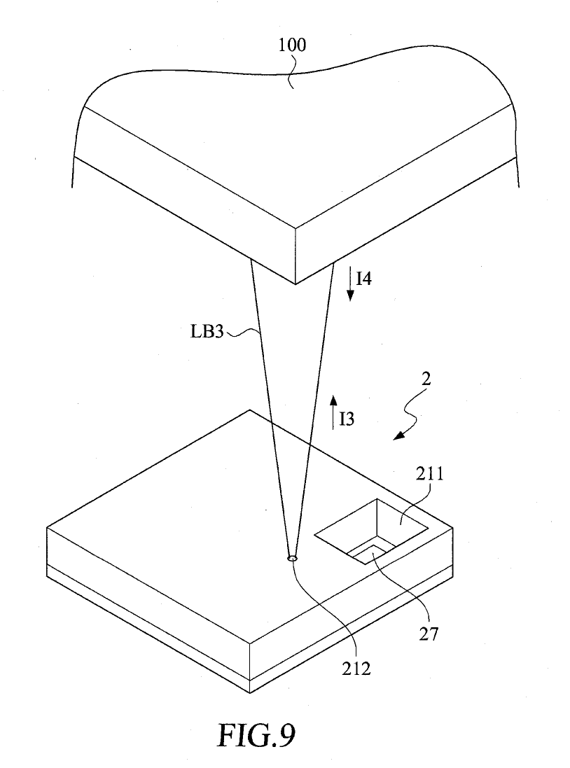

Please refer to FIG. 5 to FIG. 9, wherein FIG. 5 is a three dimensional view of an optical sensing device in accordance with a second embodiment of the present invention; FIG. 6 is a perspective view of the optical sensing device after the shell is apart from the circuit board in accordance with the second embodiment of the present invention; FIG. 7 illustrates the structure of the shell in accordance with the second embodiment of the present invention; FIG. 8 illustrates the projection direction of the light beam in accordance with the second embodiment of the present invention; FIG. 9 illustrates the working principle of that the optical sensing device is capable of sensing external relative position of the object.

As shown in FIG. 5 to FIG. 9, an optical sensing device 2 comprises a shell 21, a circuit board 22, a light emitting member 23, a shading member 24, two optical sensing members 25 and 26, and an external optical sensing member 27. The shell 21 and the circuit 22 are assembled together to form a black-body condition space therein. The shell 21 is further formed with an external sensing opening 211 and a light emitting opening 212. The black-body condition space has a light emitting chamber 213, and shading chamber 214, and two optical sensing chambers 215 and 216. The shading chamber 214 is spatially communicated with the light emitting chamber 213, and the optical sensing chambers 215 and 216. The light emitting opening 212 is outwardly bored from the light emitting chamber 213 to make the light emitting chamber 213 spatially communicated with an outer environment, and an anti-static member 217 is arranged in the shading chamber 214. Furthermore, the anti-static member 217 can be an anti-static coating partially or fully coated on the inner wall of the shading chamber 214.

The circuit board 22 is arranged with another anti-static member 221 and a grounding circuit 222, and the anti-static members 217 and 221 are electrically connected with the grounding circuit 222, so as to keep the anti-static members 217 and 221 in a grounding situation. Meanwhile, the anti-static member 221 is arranged on the circuit board 22 with respect to the shading chamber 214, and can be an anti-static circuit or an anti-static layer. When the anti-static member 217 is an anti-static coating, it can be extended out from the shading chamber 214 to contact with the grounding circuit 222 of the circuit board 22.

The light emitting member 23 is arranged in the light emitting chamber 213 and located corresponding to the light emitting opening 212, and can be a light emitting diode (LED). The shading member 24 is movably restrained in an action region AR2 within the shading chamber 214. In other words, the shading member 24 is restrained in the condition that it only can move within the action region AR2. It is more important that the shading member 24 always keeps in contacting with at least one of the anti-static members 217 and 221 when it moves within the action region AR2. The optical sensing members 25, 26 and the external optical sensing member 27 are respectively arranged in the optical sensing chambers 215, 216 and the external sensing opening 211, and can be a photo transistor or a photo diode. The external optical sensing member 27 can sense the light beam projected from the outer environment out of the optical sensing device2.

As shown in FIG. 8 and FIG. 9, besides sensing the inclination angle and the movement of the object, the optical sensing device 2 also can be directly operated to sense the relative position of an external object 100. The external object 100 herein widely implies any object out of the optical sensing device 2, such as human body, buildings or electronic device.

When the optical sensing device 2 is operated to sense the inclination angle or the movement of an object, it is able to embed the optical sensing device 2 into the object or connect the optical sensing device 2 to the object, and make the light emitting member 23 project a light beam LB2 into the light emitting chamber 213 along a projection direction 12. Due to that the working principle of the second embodiment is similar to or the same as that of the first embodiment, the related statements would not be repeated.

When the optical sensing device 2 is directly operated to sense the relative position of the external object 100, it is able to make the light emitting member 23 project an external sensing light beam LB3 via the light emitting opening 212 along another projection direction 13. When the external sensing light beam LB3 projects to the external object 100, a part of the external sensing light beam LB3 reflects from the external object 100 along a reflection direction 14, and projects to the external optical sensing member 27 arranged in the external sensing opening 211. At this moment, the external optical sensing member 27 can send out an external sensing signal in accordance with the intensity of the external sensing light beam LB3 that the external optical sensing member 27 senses, so as to accordingly judge the relative position, in which the external object 100 is located.

Any person skilled in the art can further know that the light emitting chambers 111 and 213, the shading chambers 112 and 214 and the optical sensing chambers 113, 114, 215 and 216 can be formed in many shapes, such as rhombus, square, polygon or any other irregular shape. Due to that the geometric shape is highly related to the reflection angle and the path of the light beam, it is necessary to take the geometric shape of the light emitting chambers, the shading chambers, and the optical sensing chambers into consideration when designing or manufacturing the optical sensing devices 1 and 2. Moreover, in practical applications, the light beam and the external sensing light beam can be a visible light beam (such as a white light beam) or an invisible light beam (such as an infrared light beam).

After reading the technology as disclosed in the present invention, it is believable that any person skilled in the art can further recognize that taking the first embodiment for example, in the optical sensing device 1, two anti-static members 115 and 121 are arranged in the action region AR1 where the shading number 14 is movably restrained therein; thus, no matter the shading member 14 moves to any position within the action region AR1, it always can ground the static electricity out of the black-body condition space via at least one of the anti-static members 115 and 121, so as to effectively reduce or prevent the negative influence to the exactness of optical sensing device caused by the static electricity, and further to improve the exactness for sensing the variation of the relative movement or the inclination angle.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. An optical sensing device, comprising:
a circuit board;
a shell assembled with the circuit board to form a black-body condition space having a light emitting chamber, at least one optical sensing chamber, and a shading chamber spatially communicated with the light emitting chamber and the optical sensing chamber;
at least one light emitting member arranged in the light emitting chamber for projecting at least one light beam into the light emitting chamber;
a shading member movably restrained within the shading chamber, and generating a static electricity when moving therein;
at least one anti-static member arranged in the shading chamber to ground the static electricity; and
at least one optical sensing member arranged in optical sensing chamber to sense the light beam and accordingly send out a sensing signal.

2. The optical sensing device as claimed in claim 1, wherein the circuit board further comprises a grounding circuit, and the anti-static member is electrically connected to the grounding circuit.

3. The optical sensing device as claimed in claim 2, wherein the anti-static member is an anti-static coating coated in the shading chamber.

4. The optical sensing device as claimed in claim 3, wherein the anti-static coating is extended from the shading chamber to connect to the grounding circuit.

5. The optical sensing device as claimed in claim 4, wherein the anti-static coating is formed by at least one of a vapor deposition process, a sputtering process, and a spray coating process.

6. The optical sensing device as claimed in claim 2, wherein the anti-static member is an anti-static circuit or an anti-static layer arranged on the circuit board.

7. The optical sensing device as claimed in claim 1, wherein the anti-static layer is an anti-static coating partially or fully coated on the inner wall of the shading chamber.

8. The optical sensing device as claimed in claim 1, wherein light emitting member is a light emitting diode (LED), and the optical sensing member is one of a photo transistor and a photo diode.

9. The optical sensing device as claimed in claim 1, wherein the shell is further formed with a light emitting opening and an external sensing opening, the light emitting opening is outwardly bored from the light emitting chamber to make the light emitting chamber be spatially communicated with an outer environment, and the light emitting member is located corresponding to the light emitting opening, so as to project an external sensing light beam to the outer environment via the light emitting opening.

10. The optical sensing device as claimed in claim 9, further comprising an external optical sensing member located corresponding to the external sensing opening, so as to sense the external sensing light beam after the external sensing light beam is reflected from an external object.
